(19) United States
(12) Patent Application Publication
(10) Pub. No.: US 2026/0068137 A1
(43) Pub. Date: Mar. 5, 2026

(54) MEMORY DEVICE HAVING RECESSED CONDUCTIVE PLUG AND RECESSED CHANNEL LAYER AND METHOD FOR PREPARING THE SAME

(71) Applicant: NANYA TECHNOLOGY CORPORATION, NEW TAIPEI CITY (TW)

(72) Inventor: TSENG-FU LU, NEW TAIPEI CITY (TW)

(21) Appl. No.: 18/825,216

(22) Filed: Sep. 5, 2024

(51) Int. Cl. H10B 12/00

(52) U.S. Cl. CPC H10B 12/482; H10B 12/315; H10B 12/488

(57) ABSTRACT

A memory device includes a capacitor disposed over a semiconductor substrate, and a conductive plug disposed over the capacitor. The conductive plug has a first recessed top surface. The memory device also includes a channel layer disposed over the conductive plug. The channel layer has a second recessed top surface. The memory device further includes a bit line disposed over the channel layer, and a word line disposed between the conductive plug and the bit line. The channel layer is surrounded by the word line.

### TECHNICAL FIELD

The present disclosure relates to a memory device and a method for preparing the same, and more particularly, to a memory device having a recessed conductive plug and a recessed channel layer and a method for preparing the same.

### DISCUSSION OF THE BACKGROUND

Due to structural simplicity, dynamic random access memories (DRAMs) can provide more memory cells per unit chip area than other types of memories, such as static random access memories (SRAMs). A DRAM is constituted by a plurality of DRAM cells, each of which includes a capacitor for storing information and a transistor coupled to the capacitor for regulating when the capacitor is charged or discharged. During a read operation, a word line (WL) is asserted, turning on the transistor. The enabled transistor allows the voltage across the capacitor to be read by a sense amplifier through a bit line (BL). During a write operation, the data to be written is provided on the BL while the WL is asserted.

To satisfy the demand for greater memory storage, the dimensions of the DRAM memory cells have continuously shrunk so that the packing densities of these DRAMs have increased considerably. However, the manufacturing and integration of memory devices involve many complicated steps and operations. Integration in memory devices becomes increasingly complicated. An increase in complexity of manufacturing and integration of the memory device may cause deficiencies. Accordingly, there is a continuous need to improve the structure and the manufacturing process of memory devices so that the deficiencies can be addressed, and the performance can be enhanced.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In one embodiment of the present disclosure, a memory device is provided. The memory device includes a capacitor disposed over a semiconductor substrate, and a conductive plug disposed over the capacitor. The conductive plug has a first recessed top surface. The memory device also includes a channel layer disposed over the conductive plug. The channel layer has a second recessed top surface. The memory device further includes a bit line disposed over the channel layer, and a word line disposed between the conductive plug and the bit line. The channel layer is surrounded by the word line.

In an embodiment, the second recessed top surface of the channel layer partially overlaps the first recessed top surface of the conductive plug in a top view. In an embodiment, the channel layer is in direct contact with the first recessed top surface of the conductive plug. In an embodiment, the bit line is in direct contact with the second recessed top surface of the channel layer. In an embodiment, the second recessed top surface of the channel layer is higher than a top surface of the word line.

In an embodiment, the bit line has a T-shaped profile. In an embodiment, the memory device further includes a gate dielectric layer surrounding the channel layer, wherein the word line is separated from the channel layer by the gate dielectric layer. In an embodiment, the gate dielectric layer is in direct contact with the first recessed top surface of the conductive plug. In an embodiment, a top surface of the gate dielectric layer is higher than the second recessed top surface of the channel layer.

In an embodiment, a portion of the channel layer is sandwiched between the bit line and the gate dielectric layer. In an embodiment, the bit line has a lower portion extending into the channel layer and an upper portion disposed over the lower portion, wherein the upper portion of the bit line extends laterally beyond opposite edges of the lower portion of the bit line. In an embodiment, a top surface of the gate dielectric layer is covered by and in direct contact with the upper portion of the bit line. In an embodiment, the lower portion of the bit line is separated from the gate dielectric layer.

In another embodiment of the present disclosure, a memory device is provided. The memory device includes a capacitor disposed over a semiconductor substrate, and a conductive plug disposed over the capacitor. The memory device also includes a channel layer disposed over the conductive plug. A top surface of the conductive plug is higher than a bottom surface of the channel layer. The memory device further includes a bit line disposed over the channel layer. A top surface of the channel layer is higher than a bottom surface of the bit line. In addition, the memory device includes a gate dielectric layer and a word line disposed between the conductive plug and the bit line. The gate dielectric layer is disposed between the word line and the channel layer.

In an embodiment, the channel layer is in direct contact with the conductive plug. In an embodiment, the bit line is in direct contact with the channel layer. In an embodiment, the bottom surface of the bit line is higher than a top surface of the word line. In an embodiment, the bottom surface of the channel layer is higher than a top surface of the capacitor.

In an embodiment, the channel layer is surrounded by the gate dielectric layer, and the gate dielectric layer is surrounded by the word line. In an embodiment, a top surface of the gate dielectric layer is substantially coplanar with the top surface of the channel layer. In an embodiment, the top surface of the gate dielectric layer is higher than a top surface of the word line. In an embodiment, the top surface of the conductive plug is higher than a bottom surface of the gate dielectric layer.

In an embodiment, the gate dielectric layer is in direct contact with the conductive plug. In an embodiment, the bit line has a lower portion extending into the channel layer and an upper portion disposed over the lower portion, wherein the top surface of the channel layer is covered by the upper portion of the bit line. In an embodiment, a top surface of the gate dielectric layer is covered by the upper portion of the bit line. In an embodiment, the upper portion of the bit line extends laterally beyond opposite edges of the lower portion of the bit line, wherein the edges of the lower portion of the bit line are separated from the gate dielectric layer by the channel layer.

In yet another embodiment of the present disclosure, a method for preparing a memory device is provided. The method includes forming a capacitor over a semiconductor substrate, and forming a conductive plug over the capacitor. The method also includes forming a word line over the conductive plug, and forming an opening penetrating through the word line to expose the conductive plug. The method further includes performing a first etching process through the opening to form a first recess in the conductive plug, and forming a channel layer in the opening. In addition, the method includes performing a second etching process to form a second recess in the channel layer, and forming a bit line over the channel layer.

In an embodiment, the channel layer extends into the first recess of the conductive plug. In an embodiment, the bit line extends into the second recess of the channel layer. In an embodiment, the second recess of the channel layer partially overlaps the first recess of the conductive plug in a top view. In an embodiment, before the forming the channel layer, the method further includes forming a dielectric portion over the conductive plug, forming the word line over the dielectric portion, forming a dielectric layer over the word line, and partially etching the dielectric layer, the word line and the dielectric portion to form the opening. In an embodiment, sidewalls of the word line are aligned with sidewalls of the dielectric portion.

In an embodiment, sidewalls of the conductive plug are covered by the dielectric portion after the opening is formed. In an embodiment, the method further includes forming a gate dielectric layer lining the opening before the channel layer is formed, wherein the gate dielectric layer is in direct contact with the word line. In an embodiment, the gate dielectric layer extends into the first recess to directly contact the conductive plug. In an embodiment, after the forming the channel layer, the method further includes forming a photoresist layer and dielectric spacers over the word line, wherein sidewalls of the photoresist layer are covered by the dielectric spacers. In addition, the method further includes performing the second etching process to form the second recess in the channel layer using the photoresist layer and the dielectric spacers as a mask.

In an embodiment, a top surface of the gate dielectric layer is covered by the dielectric spacers before the second etching process is performed. In an embodiment, a top surface of the channel layer is partially covered by the dielectric spacers before the second etching process is performed. In an embodiment, the bit line has a lower portion filled into the second recess of the channel layer and an upper portion disposed over the lower portion, wherein the upper portion of the bit line extends laterally beyond opposite edges of the lower portion of the bit line. In an embodiment, a top surface of the gate dielectric layer is covered by and in direct contact with the upper portion of the bit line.

Embodiments of a memory device and method for preparing the same are provided in the disclosure. In some embodiments, the memory device includes a conductive plug disposed over a capacitor, a channel layer disposed over the conductive plug, and a bit line disposed over the channel layer. In some embodiments, the conductive plug and the channel layer have recessed top surfaces. Therefore, the contact areas between the channel layer and the conductive plug and between the bit line and the channel layer are increased, and hence the contact resistances are reduced. As a result, the driving current can be increased, and the performance of the memory device can be improved. In addition, the increased contact areas provide a larger process window for memory device fabrication such as bit line landing.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

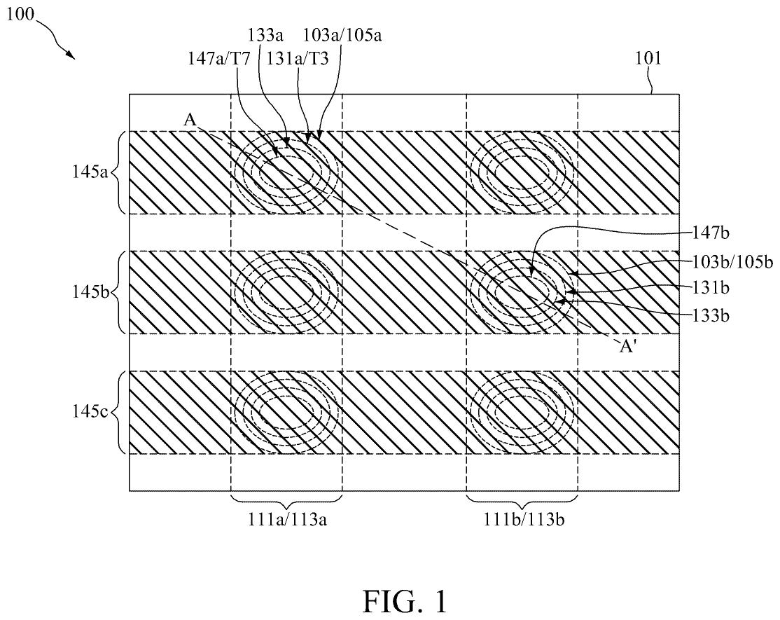

FIG. 1 is a top view illustrating a memory device, in accordance with some embodiments.

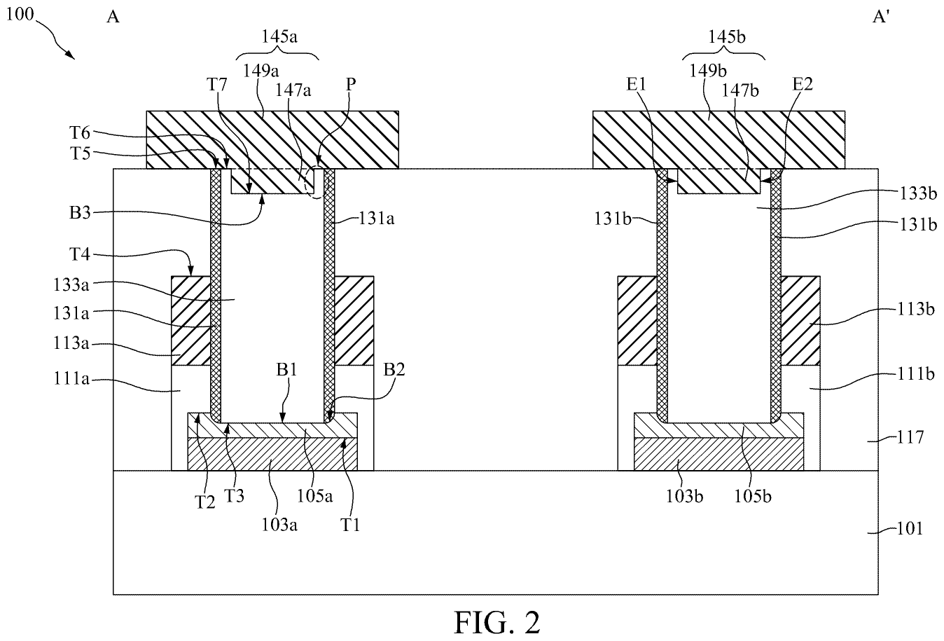

FIG. 2 is a cross-sectional view illustrating the memory device along the sectional line A-A′ in FIG. 1, in accordance with some alternative embodiments.

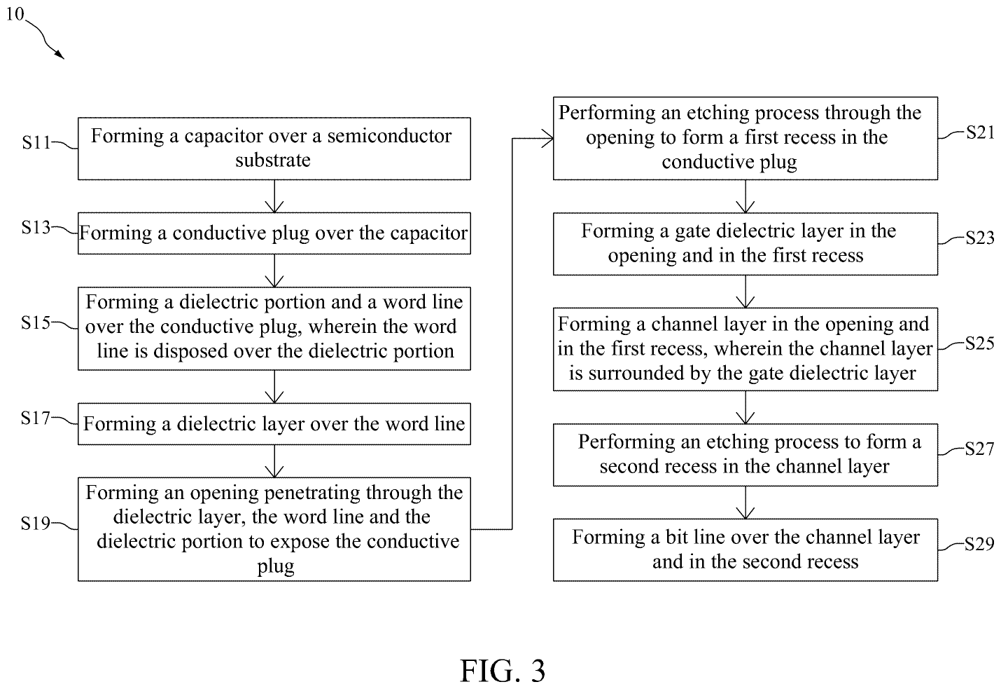

FIG. 3 is a flow diagram illustrating a method for preparing a memory device, in accordance with some embodiments.

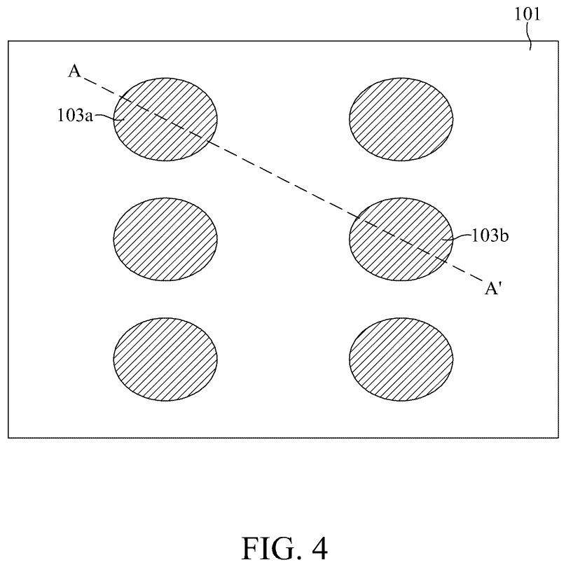

FIG. 4 is a top view illustrating an intermediate stage of forming capacitors over a semiconductor substrate during the formation of the memory device, in accordance with some embodiments.

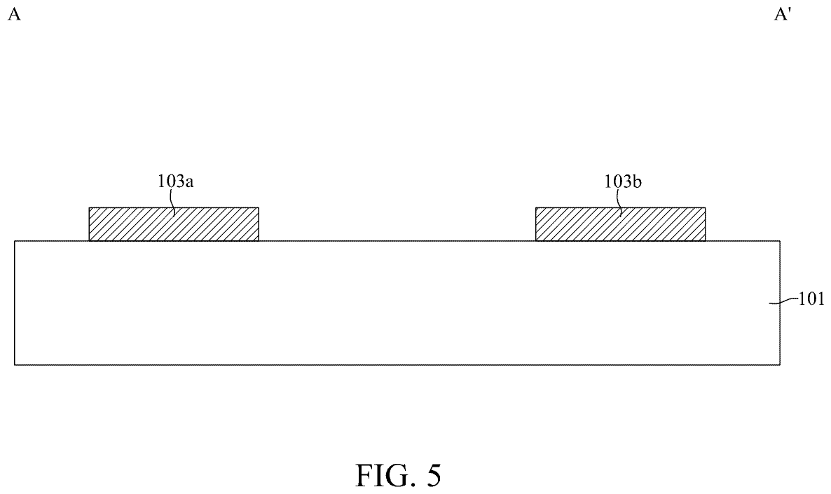

FIG. 5 is a cross-sectional view illustrating an intermediate stage in the formation of the memory device along the sectional line A-A′ in FIG. 4, in accordance with some embodiments.

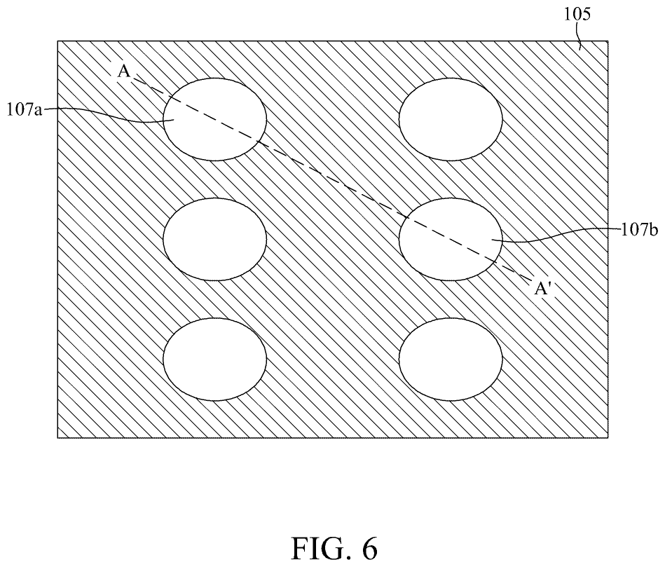

FIG. 6 is a top view illustrating an intermediate stage of forming a conductive layer over the capacitors during the formation of the memory device, in accordance with some embodiments.

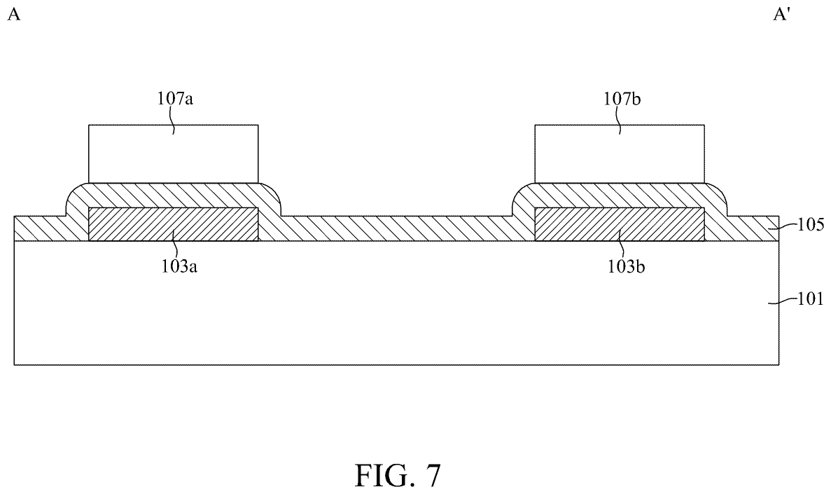

FIG. 7 is a cross-sectional view illustrating an intermediate stage in the formation of the memory device along the sectional line A-A′ in FIG. 6, in accordance with some embodiments.

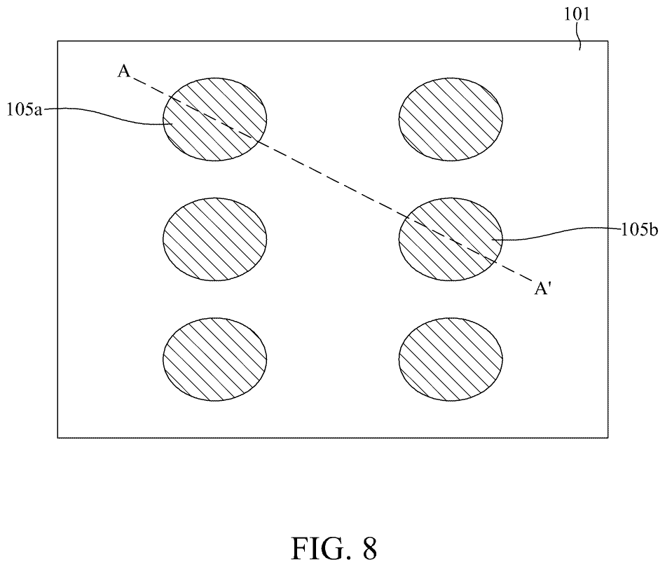

FIG. 8 is a top view illustrating an intermediate stage of etching the conductive layer to form conductive plugs during the formation of the memory device, in accordance with some embodiments.

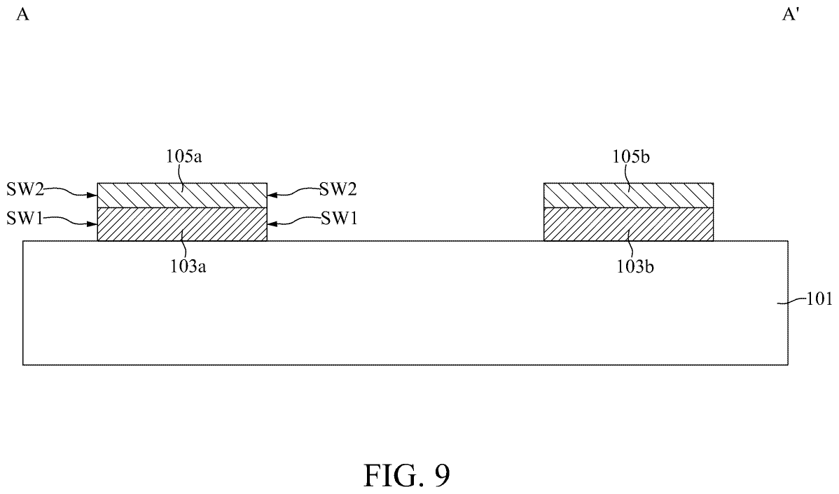

FIG. 9 is a cross-sectional view illustrating an intermediate stage in the formation of the memory device along the sectional line A-A′ in FIG. 8, in accordance with some embodiments.

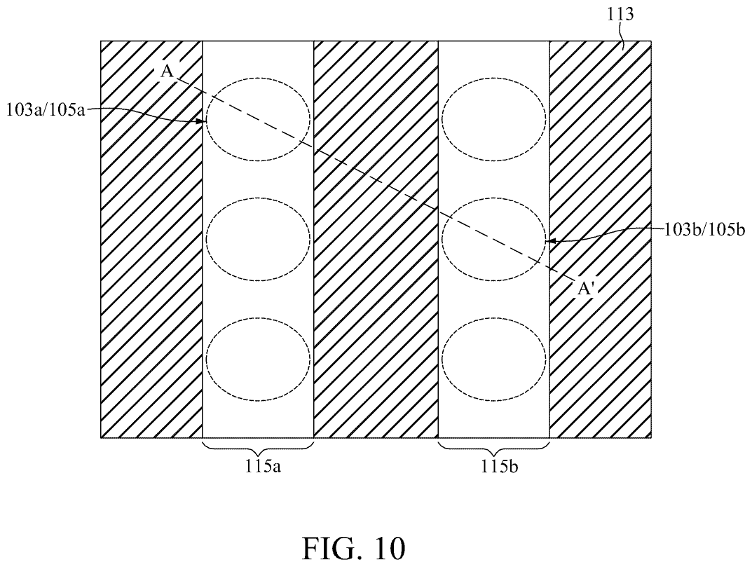

FIG. 10 is a top view illustrating an intermediate stage of sequentially forming a dielectric layer and a word line layer over the conductive plugs during the formation of the memory device, in accordance with some embodiments.

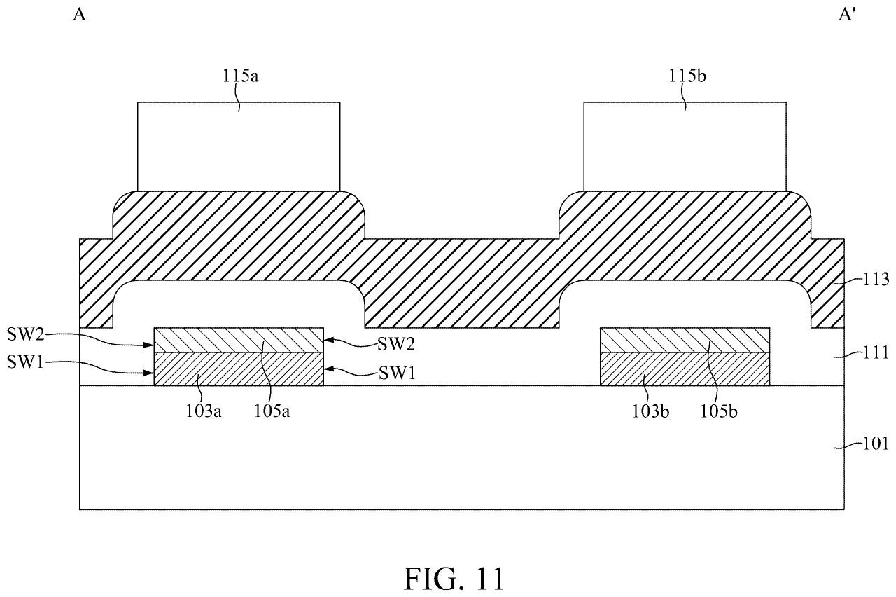

FIG. 11 is a cross-sectional view illustrating an intermediate stage in the formation of the memory device along the sectional line A-A′ in FIG. 10, in accordance with some embodiments.

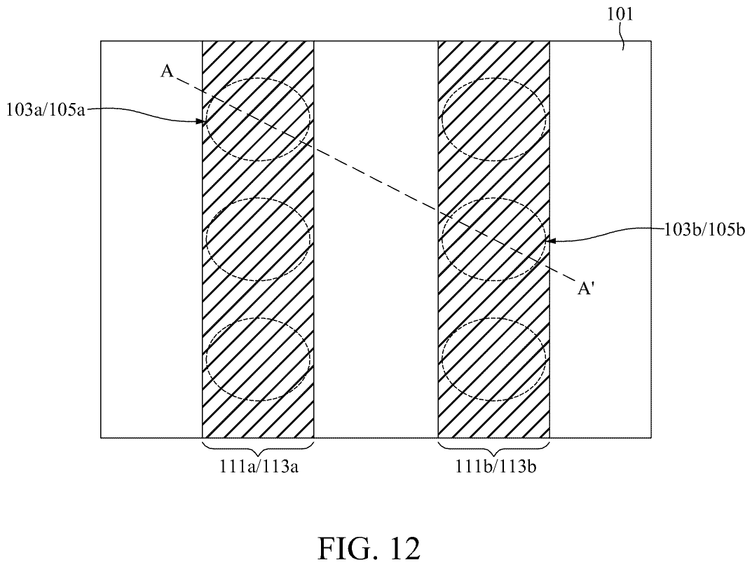

FIG. 12 is a top view illustrating an intermediate stage of etching the dielectric layer and the word line layer to form dielectric portions and word lines during the formation of the memory device, in accordance with some embodiments.

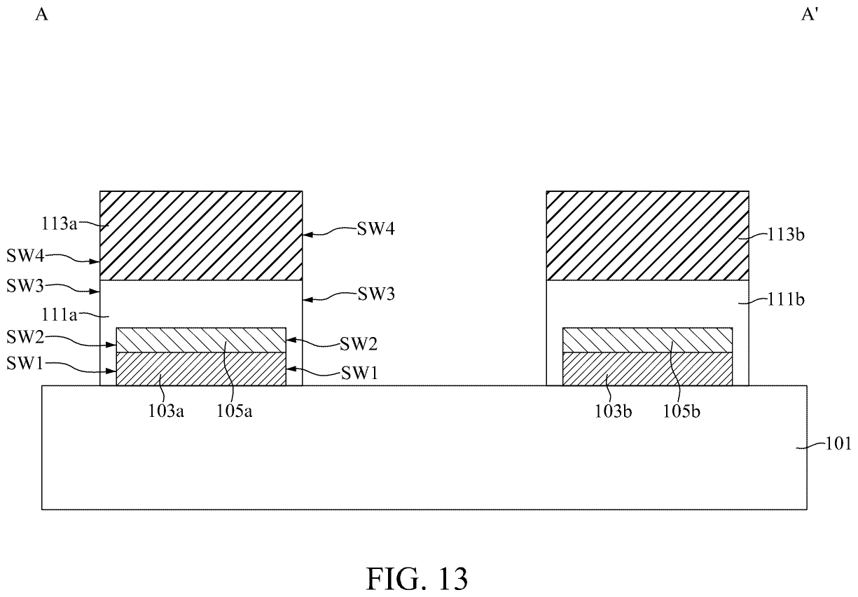

FIG. 13 is a cross-sectional view illustrating an intermediate stage in the formation of the memory device along the sectional line A-A′ in FIG. 12, in accordance with some embodiments.

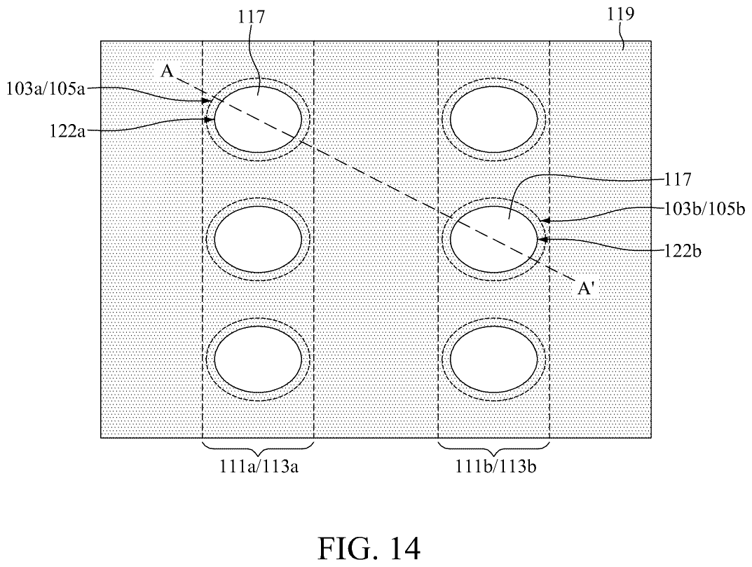

FIG. 14 is a top view illustrating an intermediate stage of forming a dielectric layer over the word lines during the formation of the memory device, in accordance with some embodiments.

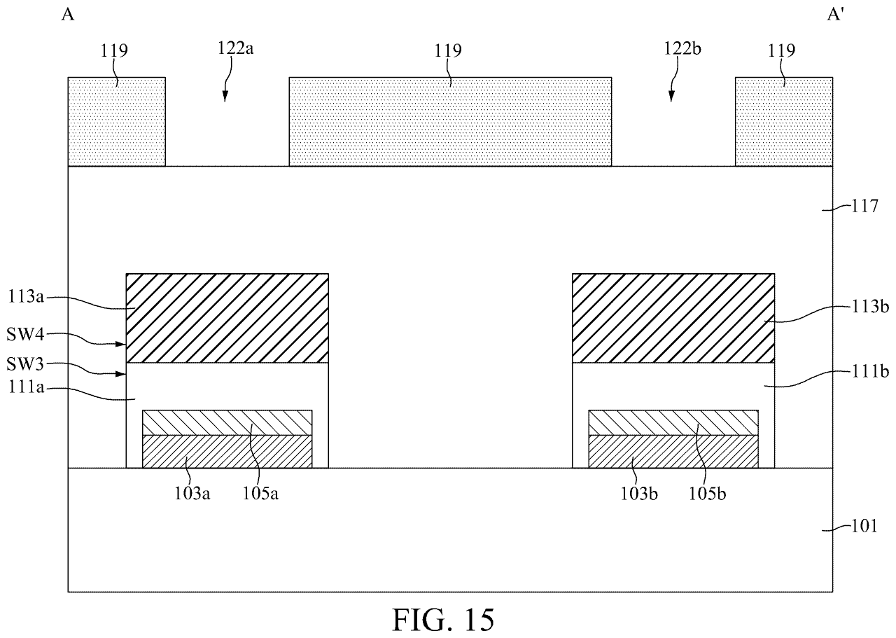

FIG. 15 is a cross-sectional view illustrating an intermediate stage in the formation of the memory device along the sectional line A-A′ in FIG. 14, in accordance with some embodiments.

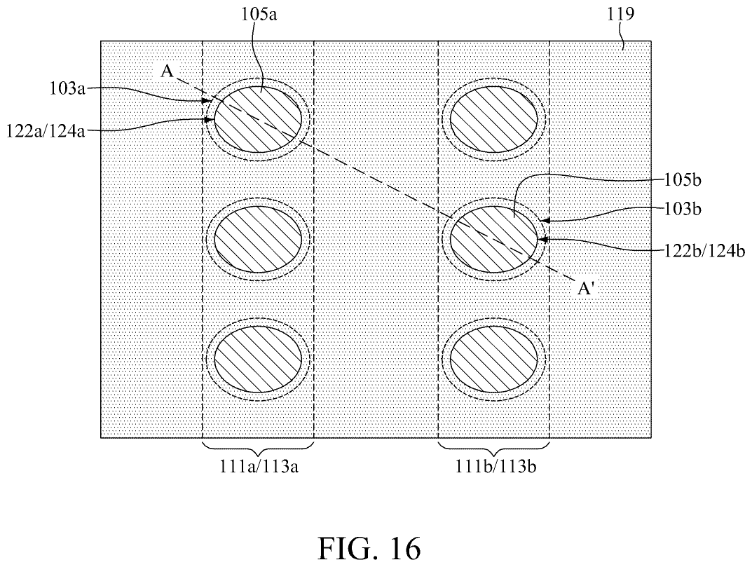

FIG. 16 is a top view illustrating an intermediate stage of forming openings exposing the conductive plugs during the formation of the memory device, in accordance with some embodiments.

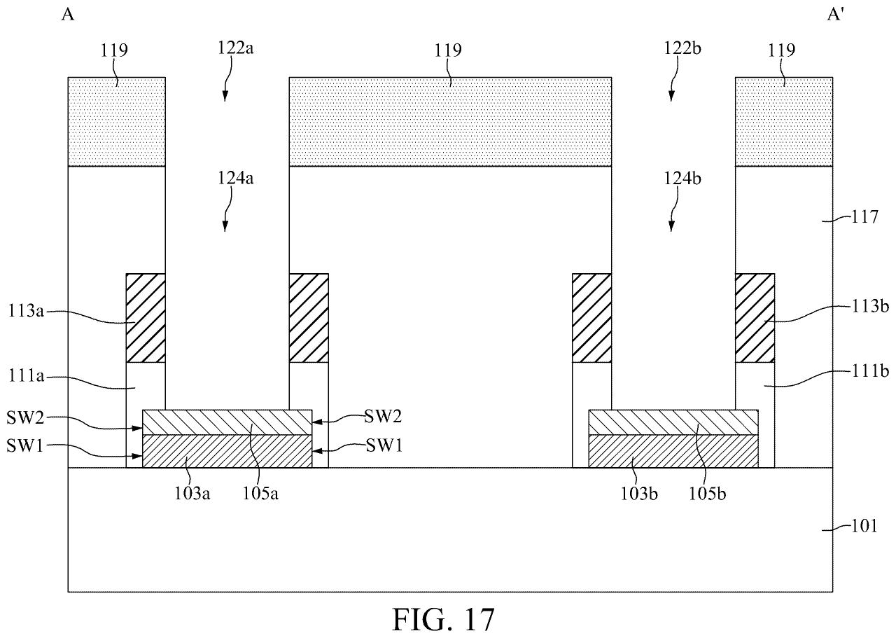

FIG. 17 is a cross-sectional view illustrating an intermediate stage in the formation of the memory device along the sectional line A-A′ in FIG. 16, in accordance with some embodiments.

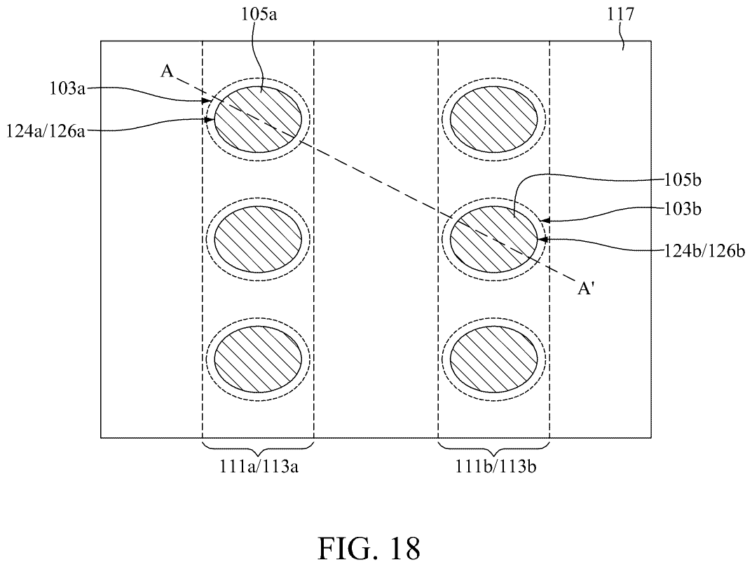

FIG. 18 is a top view illustrating an intermediate stage of etching the conductive plugs through the openings to form first recesses during the formation of the memory device, in accordance with some embodiments.

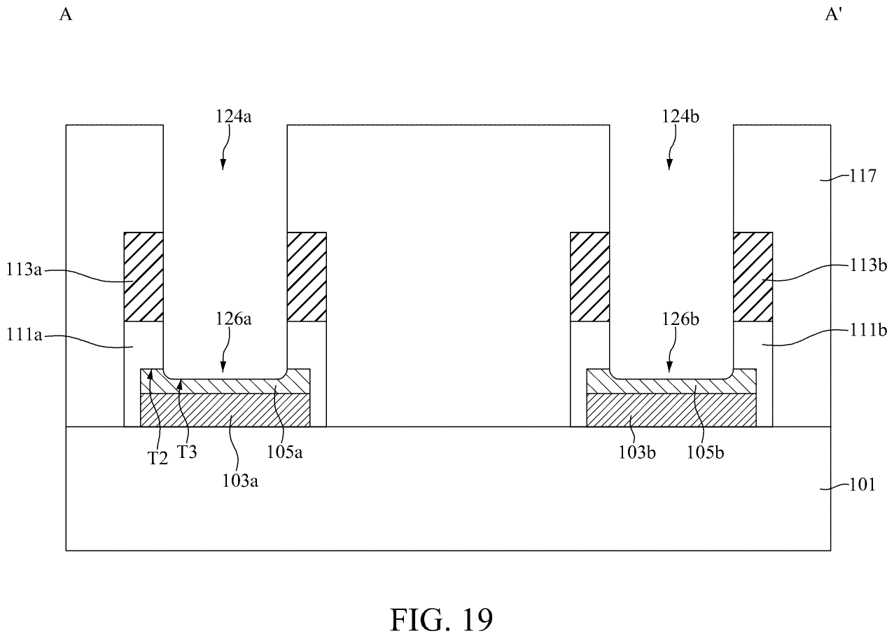

FIG. 19 is a cross-sectional view illustrating an intermediate stage in the formation of the memory device along the sectional line A-A′ in FIG. 18, in accordance with some embodiments.

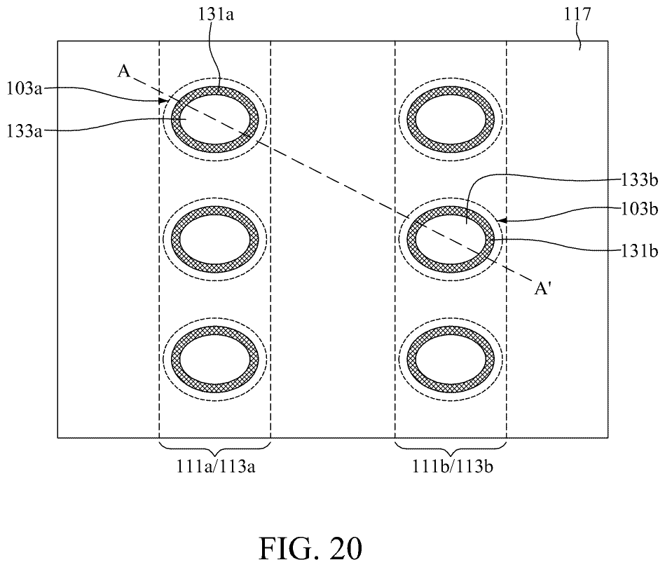

FIG. 20 is a top view illustrating an intermediate stage of forming gate dielectric layers and channel layers in the openings and in the first recesses during the formation of the memory device, in accordance with some embodiments.

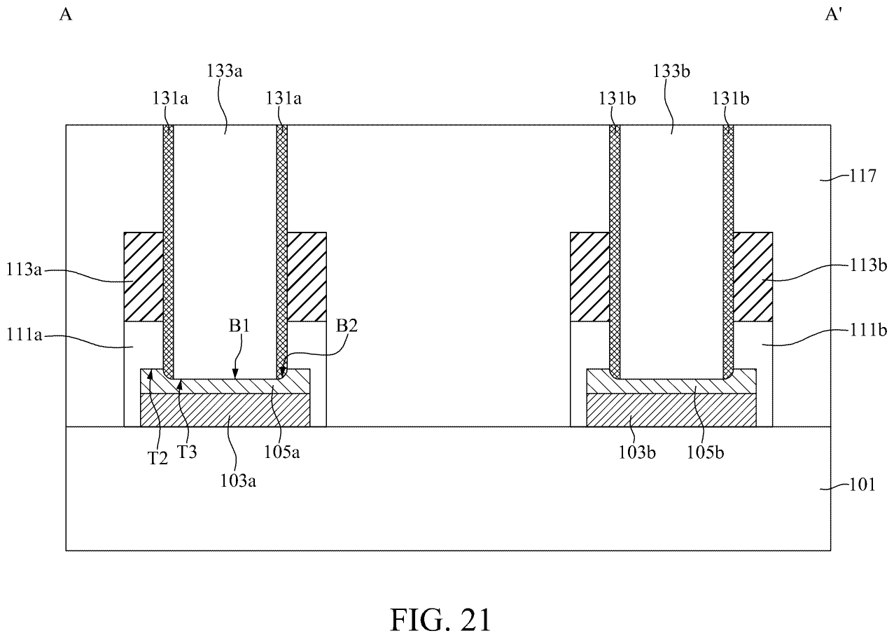

FIG. 21 is a cross-sectional view illustrating an intermediate stage in the formation of the memory device along the sectional line A-A′ in FIG. 20, in accordance with some embodiments.

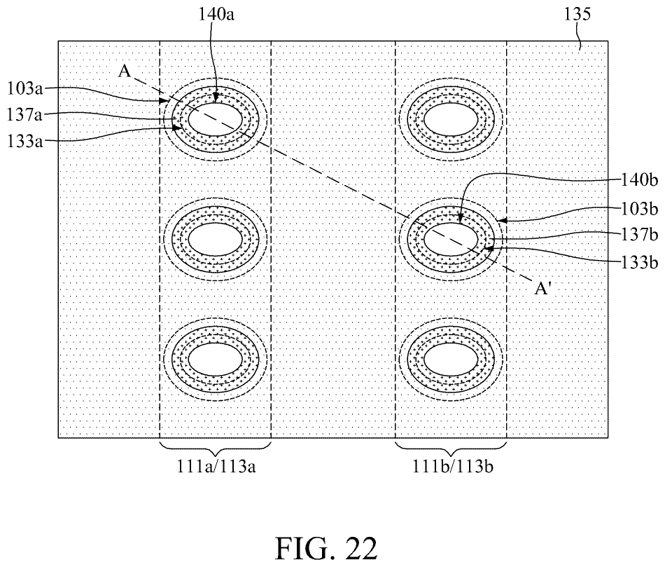

FIG. 22 is a top view illustrating an intermediate stage of forming a photoresist layer and dielectric spacers over the dielectric layer during the formation of the memory device, in accordance with some embodiments.

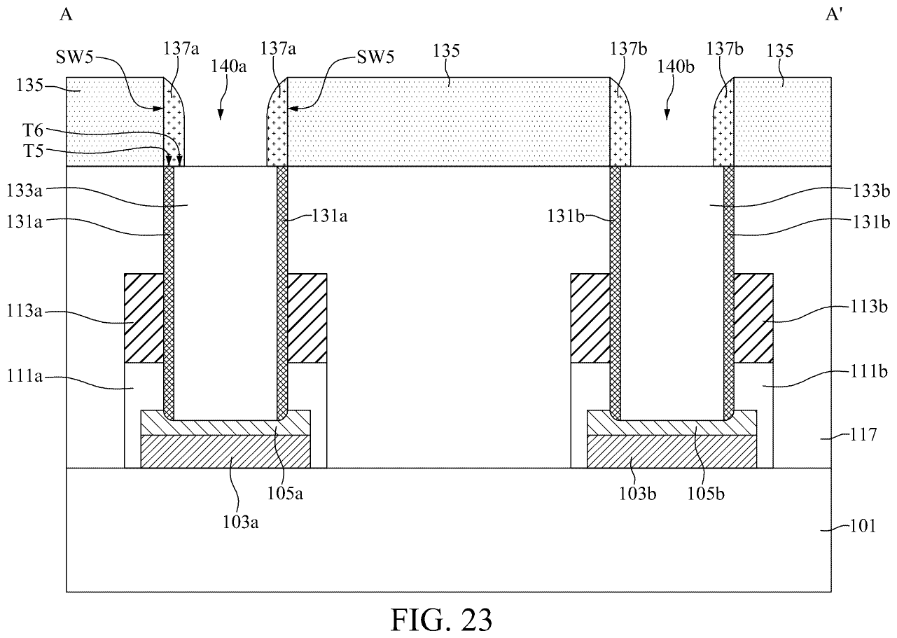

FIG. 23 is a cross-sectional view illustrating an intermediate stage in the formation of the memory device along the sectional line A-A′ in FIG. 22, in accordance with some embodiments.

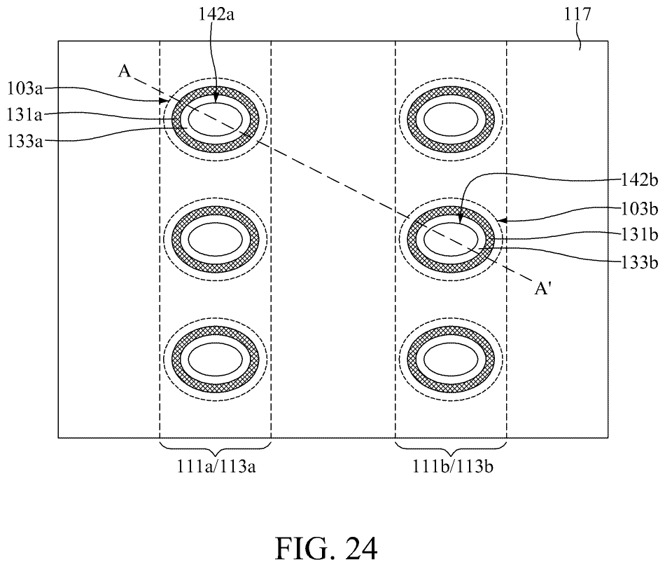

FIG. 24 is a top view illustrating an intermediate stage of etching the channel layers to form second recesses during the formation of the memory device, in accordance with some embodiments.

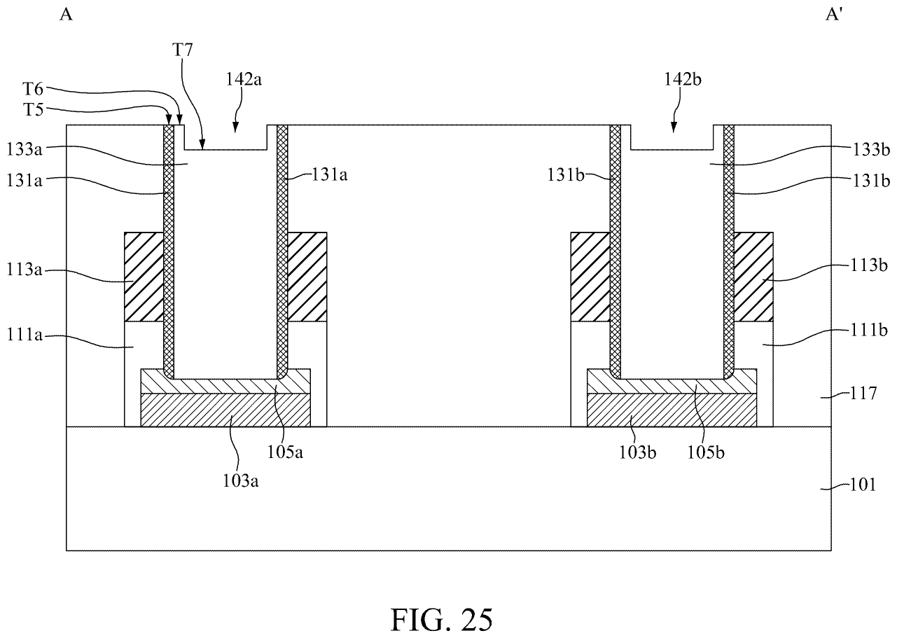

FIG. 25 is a cross-sectional view illustrating an intermediate stage in the formation of the memory device along the sectional line A-A′ in FIG. 24, in accordance with some embodiments.

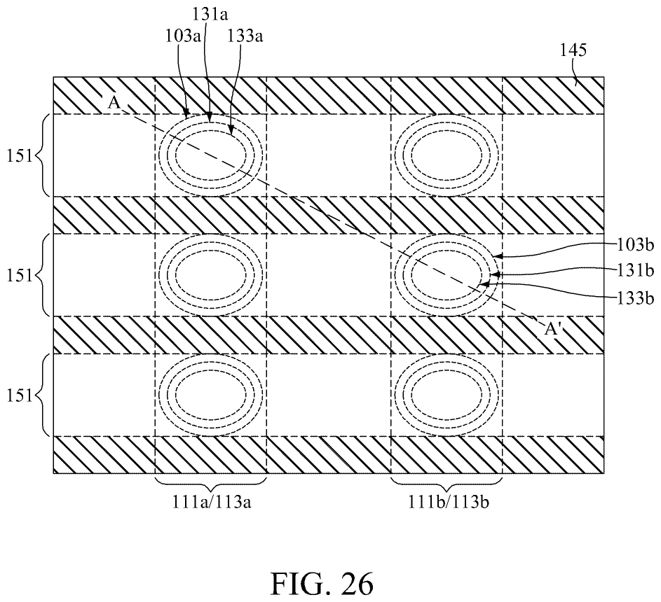

FIG. 26 is a top view illustrating an intermediate stage of forming a bit line layer over the channel layer and in the second recesses during the formation of the memory device, in accordance with some embodiments.

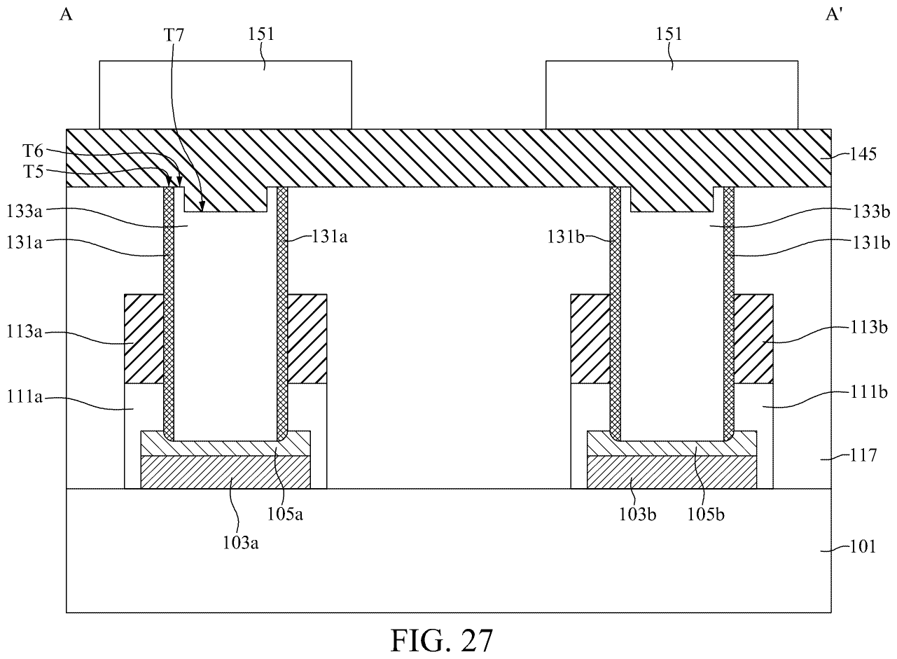

FIG. 27 is a cross-sectional view illustrating an intermediate stage in the formation of the memory device along the sectional line A-A′ in FIG. 26, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

FIG. 1 is a top view illustrating a memory device 100, FIG. 2 is a cross-sectional view illustrating the memory device 100 along the sectional line A-A′ in FIG. 1, in accordance with some embodiments.

As shown in FIGS. 1 and 2, the memory device 100 includes a semiconductor substrate 101 and a plurality of capacitors 103a and 103b disposed over the semiconductor substrate 101, in accordance with some embodiments. In some embodiments, a plurality of conductive plugs 105a and 105b are disposed over the capacitors 103a and 103b, respectively. In some embodiments, the memory device 100 includes a dielectric portion 111a disposed over the conductive plug 105a, and a word line 113a disposed over the dielectric portion 111a.

In some embodiments, the sidewalls of the capacitor 103a and the sidewalls of the conductive plug 105a are covered by the dielectric portion 111a. In some embodiments, the sidewalls of the dielectric portion 111a are substantially aligned with the sidewalls of the word line 113a. Within the context of this disclosure, the word “substantially” means preferably at least 90%, more preferably 95%, even more preferably 98%, and most preferably 99%.

In some embodiments, the memory device 100 includes a dielectric portion 111b disposed over the conductive plug 105b, and a word line 113b disposed over the dielectric portion 111b. In some embodiments, the sidewalls of the capacitor 103b and the sidewalls of the conductive plug 105b are covered by the dielectric portion 111b. In some embodiments, the sidewalls of the dielectric portion 111b are substantially aligned with the sidewalls of the word line 113b. In some embodiments, the memory device 100 includes a dielectric layer 117 disposed over the word lines 113a and 113b.

Moreover, the memory device 100 includes a gate dielectric layer 131a and a channel layer 133a penetrating through the dielectric layer 117, the word line 113a and the dielectric portion 111a, in accordance with some embodiments. In some embodiments, the channel layer 133a is surrounded by the gate dielectric layer 131a, and the gate dielectric layer 131a is surrounded by the word line 113a. In some embodiments, the channel layer 133a is separated from the dielectric layer 117, the word line 113a and the dielectric portion 111a by the gate dielectric layer 131a. In some embodiments, the gate dielectric layer 131a is in direct contact with the word line 113a and the channel layer 133a.

In some embodiments, the memory device 100 also includes a gate dielectric layer 131b and a channel layer 133b penetrating through the dielectric layer 117, the word line 113b and the dielectric portion 111b. In some embodiments, the channel layer 133b is surrounded by the gate dielectric layer 131b, and the gate dielectric layer 131b is surrounded by the word line 113b. In some embodiments, the channel layer 133b is separated from the dielectric layer 117, the word line 113b and the dielectric portion 111b by the gate dielectric layer 131b. In some embodiments, the gate dielectric layer 131b is in direct contact with the word line 113b and the channel layer 133b.

In some embodiments, the gate dielectric layer 131a and the channel layer 133a extend into the conductive plug 105a, such that a top surface T2 of the conductive plug 105a is higher than a bottom surface B1 of the channel layer 133a and a bottom surface B2 of the gate dielectric layer 131a. In some embodiments, the conductive plug 105a has a top surface T2 and a top surface T3. The top surface T3 is the top surface of the recessed portion of the conductive plug 105a. Thus, the top surface T2 is higher than the top surface T3, and the top surface T3 is referred to as a recessed top surface of the conductive plug 105a.

In some embodiments, the gate dielectric layer 131a and the channel layer 133a are in direct contact with the recessed top surface T3 of the conductive plug 105a. In some embodiments, the gate dielectric layer 131a and the channel layer 133a are separated from the capacitor 103a by a portion of the conductive plug 105a. In some embodiments, the bottom surface B1 of the channel layer 133a and the bottom surface B2 of the gate dielectric layer 131a are higher than a top surface T1 of the capacitor 103a.

It should be noted that, the above-mentioned features also present in the capacitors 103b, the conductive plug 105b, the gate dielectric layer 131b and the channel layer 133b, and are not repeated herein.

In addition, the memory device 100 includes bit lines 145a and 145b disposed over the dielectric layer 117, in accordance with some embodiments. In some embodiments, the bit line 145a is disposed over the channel layer 133a and the gate dielectric layer 131a, and the bit line 145b is disposed over the channel layer 133b and the gate dielectric layer 131b. In some embodiments, the bit line 145a is electrically connected to the capacitor 103a through the channel layer 133a and the conductive plug 105a, and the bit line 145b is electrically connected to the capacitor 103b through the channel layer 133b and the conductive plug 105b.

In some embodiments, the bit line 145a includes a lower portion 147a extending into the channel layer 133a, and an upper portion 149a disposed over the lower portion 147a. In some embodiments, the bit line 145b includes a lower portion 147b extending into the channel layer 133b, and an upper portion 149b disposed over the lower portion 147b. In some embodiments, the upper portion 149a of the bit line 145a extends laterally beyond opposite edges of the lower portion 147a of the bit line 145a, and the upper portion 149b of the bit line 145b extends laterally beyond opposite edges of the lower portion 147b of the bit line 145b (e.g., the opposite edges E1 and E2 of the lower portion 147b of the bit line 145b). As a result, the bit lines 145a and 145b have T-shaped profiles in the cross-sectional view of FIG. 2.

In some embodiments, the opposite edges of the lower portions 147a, 147b of the bit lines 145a, 145b (e.g., the opposite edges E1 and E2) are separated from the gate dielectric layer 131a, 131b by the channel layers 133a, 133b. In some embodiments, the channel layer 133a has a portion sandwiched between the lower portion 147a of the bit line 145a and the gate dielectric layer 131a, and the channel layer 133b has a portion sandwiched between the lower portion 147b of the bit line 145b and the gate dielectric layer 131b. For example, a portion P of the channel layer 133a is sandwiched between lower portion 147a of the bit line 145a and the gate dielectric layer 131a.

In some embodiments, the bit line 145a extends into the channel layer 133a, such that a top surface T6 of the channel layer 133a is higher than a bottom surface B3 of the bit line 145a. In some embodiments, the channel layer 133a has a top surface T6 and a top surface T7. The top surface T7 is the top surface of the recessed portion of the channel layer 133a. Thus, the top surface T6 is higher than the top surface T7, and the top surface T7 is referred to as a recessed top surface of the channel layer 133a.

In some embodiments, the recessed top surface T3 of the conductive plug 105a partially overlaps the recessed top surface T7 of the channel layer 133a in the top view of FIG. 1. In some embodiments, the bit line 145a is in direct contact with the recessed top surface T7 of the channel layer 133a. In some embodiments, the recessed top surface T7 of the channel layer 133a is higher than a top surface T4 of the word line 113a.

In some embodiments, a top surface T5 of the gate dielectric layer 131a is substantially coplanar with the top surface T6 of the channel layer 133a. In some embodiments, the top surface T5 of the gate dielectric layer 131a and the top surface T6 of the channel layer 133a are higher than the recessed top surface T7 of the channel layer 133a. In some embodiments, the top surface T5 of the gate dielectric layer 131a and the top surface T6 of the channel layer 133a are higher than the top surface T4 of the word line 113a.

It should be noted that, the above-mentioned features also present in the word line 113b, the gate dielectric layer 131b, the channel layer 133b and the bit line 145b, and are not repeated herein.

In some embodiments, the memory device 100 includes the conductive plugs 105a, 105b disposed over the capacitors 103a, 103b, the channel layers 133a, 133b disposed over the conductive plugs 105a, 105b, and the bit lines 145a, 145b disposed over the channel layers 133a, 133b. In some embodiments, the conductive plugs 105a, 105b and the channel layers 133a, 133b have recessed top surfaces. Therefore, the contact areas between the channel layers 133a, 133b and the conductive plugs 105a, 105b are increased, and the contact areas between the bit lines 145a, 145b and the channel layers 133a, 133b are increased. Hence, the contact resistances are reduced. As a result, the driving current can be increased, and the performance of the memory device 100 can be improved. In addition, the increased contact areas provide a larger process window for memory device fabrication such as bit line landing.

FIG. 3 is a flow diagram illustrating a method 10 for preparing the memory device 100, and the method 10 includes steps S11, S13, S15, S17, S19, S21, S23, S25, S27 and S29, in accordance with some embodiments. The steps S11 to S29 of FIG. 3 are elaborated in connection with FIGS. 4 to 27.

FIGS. 4, 6, 8, 10, 12, 14, 16, 18, 20, 22, 24 and 26 are top views illustrating intermediate stages in the formation of the memory device 100, and FIGS. 5, 7, 9, 11, 13, 15, 17, 19, 21, 23, 25 and 27 are cross-sectional views illustrating intermediate stages in the formation of the memory device 100, in accordance with some embodiments. It should be noted that FIGS. 5, 7, 9, 11, 13, 15, 17, 19, 21, 23, 25 and 27 are cross-sectional views along the sectional line A-A′ of FIGS. 4, 6, 8, 10, 12, 14, 16, 18, 20, 22, 24 and 26, respectively.

As shown in FIGS. 4 and 5, a semiconductor substrate 101 is provided. The semiconductor substrate 101 may be or may include a package substrate, an interposer, a printed circuit board (PCB), and/or other circuit carrier that is capable of carrying integrated circuits (IC).

The semiconductor substrate 101 may include various passive and active microelectronic devices, such as resistors, capacitors, inductors, diodes, p-type field effect transistors (pFETs), n-type field effect transistors (nFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, fin field-effect transistors (FinFETs), other suitable integrated circuit (IC) components, or combinations thereof.

Moreover, the semiconductor substrate 101 may include various material layers (e.g., dielectric layers, semiconductor layers, and/or conductive layers) configured to form IC features (e.g., doped regions, isolation features, gate features, source/drain features, interconnect features, other features, or combinations thereof). The semiconductor substrate 101 has been simplified for the sake of clarity. It should be noted that additional features can be added in the semiconductor substrate 101, and some of the features described below can be replaced, modified, or eliminated in other embodiments.

Still referring to FIGS. 4 and 5, a plurality of capacitors 103a and 103b are formed over the semiconductor substrate 101, in accordance with some embodiments. The respective step is illustrated as the step S11 in the method 10 shown in FIG. 3. In some alternative embodiments, the capacitors 103a and 103b are formed in the semiconductor substrate 101. In some embodiments, the capacitors 103a and 103b are separated from each other.

Next, a conductive layer 105 is formed over the semiconductor substrate 101, and a patterned mask including patterns 107a and 107b is formed over the conductive layer 105, as shown in FIGS. 6 and 7 in accordance with some embodiments. In some embodiments, the sidewalls and the top surfaces of the capacitors 103a, 103b are covered by the conductive layer 105. In some embodiments, the pattern 107a of the patterned mask overlaps the capacitor 103a, and the pattern 107b of the patterned mask overlaps the capacitor 103b in the top view of FIG. 6.

In some embodiments, the conductive layer 105 includes aluminum (Al), copper (Cu), tungsten (W), titanium (Ti), tantalum (Ta), a combination thereof, or another suitable conductive material. In some embodiments, the conductive layer 105 is formed by a deposition process, such as a chemical vapor deposition (CVD) process, a physical vapor deposition (PVD) process, an atomic layer deposition (ALD) process, a spin-on coating process, or another suitable deposition process. In some embodiments, the conductive layer 105 and the patterned mask with the patterns 107a, 107b include different materials so that the etching selectivities may be different in the subsequent etching process.

Subsequently, the conductive layer 105 is etched by using the patterned mask with patterns 107a and 107b as a mask, such that conductive plugs 105a and 105b are formed over the capacitors 103a and 103b, as shown in FIGS. 8 and 9 in accordance with some embodiments. The respective step is illustrated as the step S13 in the method 10 shown in FIG. 3. In some embodiments, the conductive layer 105 is etched by a wet etching process, a dry etching process, or a combination thereof.

In some embodiments, the conductive plugs 105a and 105b overlap the capacitors 103a and 103b in the top view of FIG. 8. In some embodiments, the sidewalls of the capacitors 103a and 103b are substantially aligned with the sidewalls of the conductive plugs 105a and 105b. For example, the sidewalls SW1 of the capacitor 103a are substantially aligned with the sidewalls SW2 of the conductive plug 105a. After the conductive plugs 105a and 105b are formed, the patterned mask with the patterns 107a and 107b (see FIGS. 6 and 7) may be removed. In some embodiments, the patterned mask is removed by a stripping process, an ashing process, an etching process, or another suitable process.

Then, a dielectric layer 111 is formed over the semiconductor substrate 101, and a word line layer 113 is formed over the dielectric layer 111, as shown in FIGS. 10 and 11 in accordance with some embodiments. In some embodiments, the sidewalls of the conductive plugs 105a, 105b and the sidewalls of the capacitors 103a, 103b are covered by the dielectric layer 111. For example. The sidewalls SW1 of the capacitor 103a and the sidewalls SW2 of the conductive plug 105a are covered by the dielectric layer 111.

In some embodiments, the dielectric layer 111 includes silicon nitride, silicon oxide, silicon oxynitride, a combination thereof, or another suitable dielectric material. In some embodiments, the dielectric layer 111 is formed by a deposition process, such as a CVD process, a PVD process, an ALD process, a spin-on coating process, or another suitable deposition process. In some embodiments, the word line layer 113 includes polysilicon, aluminum (Al), copper (Cu), tungsten (W), titanium (Ti), tantalum (Ta), a combination thereof, or another suitable material. In some embodiments, the word line layer 113 is formed by a CVD process, a PVD process, a sputtering process, a plating process, or another suitable process.

Still referring to FIGS. 10 and 11, a patterned mask including patterns 115a and 115b are formed over the word line layer 113, in accordance with some embodiments. In some embodiments, the pattern 115a of the patterned mask is arranged parallelly with the pattern 115b of the patterned mask. In some embodiments, the conductive plug 105a overlaps the pattern 115a of the patterned mask, and the conductive plug 105b overlaps the pattern 115b of the patterned mask in the top view of FIG. 10.

Next, the word line layer 113 and the dielectric layer 111 are etched by using the patterned mask with patterns 115a and 115b as a mask, such that word lines 113a, 113b and dielectric portions 111a, 111b are formed over the conductive plugs 105a, 105b, as shown in FIGS. 12 and 13 in accordance with some embodiments. The respective step is illustrated as the step S15 in the method 10 shown in FIG. 3. In some embodiments, the word line layer 113 and the dielectric layer 111 are etched by a wet etching process, a dry etching process, or a combination thereof.

In some embodiments, the sidewalls of the word lines 113a and 113b are substantially aligned with the sidewalls of the dielectric portions 111a and 111b. For example, the sidewalls SW4 of the word line 113a are substantially aligned with the sidewalls SW3 of the dielectric portion 111a. In some embodiments, the sidewalls of the capacitors 103a, 103b and the sidewalls of the conductive plugs 105a, 105b are covered by the dielectric portions 111a, 111b. For example, the sidewalls SW1 of the capacitor 103a and the sidewalls SW2 of the conductive plug 105a are covered by the dielectric portion 111a.

After the word lines 113a, 113b and the dielectric portions 111a, 111b are formed, the patterned mask with the patterns 115a and 115b (see FIGS. 10 and 11) may be removed. In some embodiments, the patterned mask is removed by a stripping process, an ashing process, an etching process, or another suitable process.

Subsequently, a dielectric layer 117 is formed over the semiconductor substrate 101, and a patterned mask 119 with openings 122a and 122b is formed over the dielectric layer 117, as shown in FIGS. 14 and 15 in accordance with some embodiments. In some embodiments, the word lines 113a and 113b are covered by the dielectric layer 117. In some embodiments, the sidewalls of the word lines 113a, 113b and the sidewalls of the dielectric portions 111a, 111b are covered by the dielectric layer 117. For example, the sidewalls SW3 of the dielectric portion 111a and the sidewalls SW4 of the word line 113a are covered by the dielectric layer 117.

In some embodiments, the dielectric layer 117 is partially exposed by the openings 122a and 122b of the patterned mask 119. In addition, the opening 122a of the patterned mask 119 overlaps the capacitor 103a and the conductive plug 105a, and the opening 122b of the patterned mask 119 overlaps the capacitor 103b and the conductive plug 105b in the top view of FIG. 14, in accordance with some embodiments. The respective step is illustrated as the step S17 in the method 10 shown in FIG. 3.

Then, a plurality of openings 124a and 124b are formed penetrating through the dielectric layer 117, the word lines 113a, 113b, and the dielectric portions 111a, 111b to expose the conductive plugs 105a and 105b using the patterned mask 119 as a mask, as shown in FIGS. 16 and 17 in accordance with some embodiments. The respective step is illustrated as the step S19 in the method 10 shown in FIG. 3. In some embodiments, the openings 124a and 124b are formed by performing a wet etching process, a dry etching process, or a combination thereof.

In some embodiments, the top surface of the conductive plug 105a is partially exposed by the opening 124a, and the top surface of the conductive plug 105b is partially exposed by the opening 124b. In some embodiments, after the openings 124a and 124b are formed, the top surface of the conductive plug 105a is partially covered by the remaining portion of the dielectric portion 111a, and the top surface of the conductive plug 105b is partially covered by the remaining portion of the dielectric portion 111b. Moreover, in some embodiments, the sidewalls of the conductive plugs 105a, 105b and the sidewalls of the capacitors 103a, 103b are covered by the remaining portions of the dielectric portions 111a, 111b after the openings 124a and 124b are formed. For example, the sidewalls SW1 of the capacitor 103a and the sidewalls SW2 of the conductive plug 105a are covered by the remaining portion of the dielectric portion 111a.

After the conductive plugs 105a and 105b are exposed by the openings 124a and 124b, the patterned mask 119 may be removed. In some embodiments, the patterned mask 119 is removed by a stripping process, an ashing process, an etching process, or another suitable process.

Next, an etching process is performed through the openings 124a, 124b to form first recesses 126a, 126b in the conductive plugs 105a, 105b, as shown in FIGS. 18 and 19 in accordance with some embodiments. The respective step is illustrated as the step S21 in the method 10 shown in FIG. 3. In some embodiments, after the first recesses 126a and 126b are formed, the top surfaces of the portions of the conductive plugs 105a, 105b covered by the dielectric portions 111a, 111b (i.e., the top surfaces of the portions of the conductive plugs 105a, 105b not recessed by the etching process) are higher than the top surfaces of the recessed portions of the conductive plugs 105a, 105b.

For example, the top surface T2 of the portion of the conductive plug 105a covered by the dielectric portion 111a is higher than the top surface T3 of the recessed portion of the conductive plug 105a. In some embodiments, the etching process includes a wet etching process, a dry etching process, or a combination thereof.

Subsequently, gate dielectric layers 131a, 131b and channel layers 133a and 133b are formed in the openings 124a, 124b and in the first recesses 126a, 126b, as shown in FIGS. 20 and 21 in accordance with some embodiments. In some embodiments, the channel layer 133a is surrounded by the gate dielectric layer 131a, and the channel layer 133b is surrounded by the gate dielectric layer 131b. The respective steps are illustrated as the steps S23 and S25 in the method 10 shown in FIG. 3.

In some embodiments, the bottom surfaces of the gate dielectric layers 131a, 131b and the bottom surfaces of the channel layers 133a and 133b are lower than the top surfaces of the portions of the conductive plugs 105a and 105b covered by the dielectric portions 111a and 111b (i.e., the top surfaces of the portions of the conductive plugs 105a and 105b not recessed by the etching process). For example, the top surface T2 of the portion of the conductive plug 105a is covered by the dielectric portion 111a, and the bottom surface B1 of the channel layer 133a and the bottom surface B2 of the gate dielectric layer 131a are lower than the top surface T2.

In some embodiments, the bottom surfaces of the gate dielectric layers 131a, 131b and the bottom surfaces of the channel layers 133a and 133b are in direct contact with the recessed top surfaces of the conductive plugs 105a and 105b. For example, the bottom surface B1 of the channel layer 133a and the bottom surface B2 of the gate dielectric layer 131a are in direct contact with the recessed top surface T3 of the conductive plug 105a.

In some embodiments, the gate dielectric layers 131a and 131b include silicon oxide, silicon nitride, silicon oxynitride, a combination thereof, or another suitable dielectric material. In some embodiments, the channel layers 133a and 133b include indium gallium zinc oxide (InGaZnO). However, any other suitable materials may be utilized, such as indium zinc oxide (InZnO), indium tin oxide (InSnO), indium oxide (InOₓ), gallium oxide (GaOₓ).

In some embodiments, the formations of the gate dielectric layers 131a, 131b and the channel layers 133a, 133b include sequentially depositing a gate dielectric material (not shown) and a channel material (not shown) in the openings 124a, 124b and in the recesses 126a, 126b, and over the dielectric layer 117, and performing a planarization process to remove excess portions of the gate dielectric material and the channel material outside the openings 124a, 124b and the recesses 126a, 126b. The deposition process may include a CVD process, a PVD process, an ALD process, a spin-on coating process, or another suitable deposition process. The planarization process may include a chemical mechanical polishing (CMP) process.

Then, a photoresist layer 135 is formed over the dielectric layer 117, and a plurality of dielectric spacers 137a and 137b are formed covering sidewalls of the photoresist layer 135, as shown in FIGS. 22 and 23 in accordance with some embodiments. For example, the sidewalls SW5 of the photoresist layer 135 are covered by the dielectric spacers 137a. After the photoresist layer 135 and the dielectric spacers 137a, 137b are formed, the channel layer 133a is partially exposed by the opening 140a, and the channel layer 133b is partially exposed by the opening 140b, in accordance with some embodiments.

In some embodiments, the top surfaces of the gate dielectric layers 131a and 131b are covered by the dielectric spacers 137a and 137b. For example, the top surface T5 of the gate dielectric layer 131a is covered by the dielectric spacers 137a. In some embodiments, the top surfaces of the channel layers 133a and 133b are partially covered by the dielectric spacers 137a and 137b. For example, the top surface T6 of the channel layer 133a is partially covered by the dielectric spacers 137a.

In some embodiments, the dielectric spacers 137a and 137b are formed after the formation of the photoresist layer 135. The formation of the dielectric spacers 137a and 137b may include depositing a dielectric layer (not shown) over the photoresist layer 135, performing an etching process to remove the horizontal portions of the dielectric layer, leaving the vertical portions of the dielectric layer. The remaining vertical portions of the dielectric layer are referred to as the dielectric spacers 137a and 137b. In some embodiments, the etching process is an anisotropic etching process.

Next, an etching process is performed to form second recesses 142a, 142b in the channel layers 133a, 133b using the photoresist layer 135 and the dielectric spacers 137a, 137b as a mask, as shown in FIGS. 24 and 25 in accordance with some embodiments. The respective step is illustrated as the step S27 in the method 10 shown in FIG. 3. After the second recesses 142a and 142b are formed, the photoresist layer 135 and the dielectric spacers 137a, 137b may be removed.

In some embodiments, after the second recesses 142a and 142b are formed, the top surfaces of the portions of the channel layers 133a, 133b covered by the dielectric spacers 137a, 137b are higher than the top surfaces of the recessed portions of the channel layers 133a, 133b. For example, the top surface T6 of the portion of the channel layer 133a covered by the dielectric spacers 137a (see FIGS. 22 and 23) are higher than the top surface T7 of the recessed portion of the channel layer 133a. In some embodiments, the top surfaces of the gate dielectric layers 131a, 131b are higher than the top surfaces of the recessed portions of the channel layers 133a, 133b. For example, the top surface T5 of the gate dielectric layer 131a is higher than the top surface T7 of the recessed portion of the channel layer 133a.

In some embodiments, the second recesses 142a, 142b of the channel layers 133a, 133b partially overlap the first recesses 126a, 126b of the conductive plugs 103a, 103b (see FIGS. 18 and 19) in the top view of FIG. 24. In some embodiments, the etching process includes a wet etching process, a dry etching process, or a combination thereof.

Subsequently, a bit line layer 145 is formed in the second recesses 142a, 142b and over the dielectric layer 117, and a patterned mask 151 is formed over the bit line layer 145, as shown in FIGS. 26 and 27 in accordance with some embodiments. In some embodiments, the top surfaces of the gate dielectric layers 131a, 131b, and the top surfaces of the channel layers 133a, 133b are covered by the bit line layer 145. For example, the top surfaces T5, T6 and T7 are covered by the bit line layer 145.

In some embodiments, the bit line layer 145 includes aluminum (Al), copper (Cu), tungsten (W), titanium (Ti), tantalum (Ta), a combination thereof, or another suitable material. In some embodiments, the bit line layer 145 is formed by a deposition process, such as a CVD process, a PVD process, an ALD process, a sputtering process, a plating process, or another suitable deposition process.

Referring back to FIGS. 1 and 2, the bit line layer 145 is etched by using the patterned mask 151 as a mask, such that bit lines 145a and 145b are formed, in accordance with some embodiments. In some embodiments, the bit line 145a is formed over the channel layer 133a and in the second recess 142a (see FIGS. 24 and 25), and the bit line 145b is formed over the channel layer 133b and in the second recess 142b (see FIGS. 24 and 25). The respective step is illustrated as the step S29 in the method 10 shown in FIG. 3.

In some embodiments, the bit line layer 145 is etched by a wet etching process, a dry etching process, or a combination thereof. After the bit lines 145a and 145b are formed, the patterned mask 151 (see FIGS. 26 and 27) may be removed. In some embodiments, the patterned mask 151 is removed by a stripping process, an ashing process, an etching process, or another suitable process. After the patterned mask 151 is removed, the memory device 100 is completed. In some embodiments, the memory device 100 is part of a DRAM.

Embodiments of the memory device 100 and methods for preparing the same are provided in the disclosure. In some embodiments, the memory device 100 includes the conductive plugs 105a, 105b disposed over the capacitors 103a, 103b, the channel layers 133a, 133b disposed over the conductive plugs 105a, 105b, and the bit lines 145a, 145b disposed over the channel layers 133a, 133b. In some embodiments, the conductive plugs 105a, 105b have recessed top surfaces (e.g., top surface T3), and the channel layers 133a, 133b have recessed top surfaces (e.g., top surface T7). Therefore, the contact areas between the channel layers 133a, 133b and the conductive plugs 105a, 105b are increased, and the contact areas between the bit lines 145a, 145b and the channel layers 133a, 133b are increased. Hence, the contact resistances are reduced. As a result, the driving current can be increased, and the performance of the memory device 100 can be improved. In addition, the increased contact areas provide a larger process window for memory device fabrication such as bit line landing.

In one embodiment of the present disclosure, a memory device is provided. The memory device includes a capacitor disposed over a semiconductor substrate, and a conductive plug disposed over the capacitor. The conductive plug has a first recessed top surface. The memory device also includes a channel layer disposed over the conductive plug. The channel layer has a second recessed top surface. The memory device further includes a bit line disposed over the channel layer, and a word line disposed between the conductive plug and the bit line. The channel layer is surrounded by the word line.

In another embodiment of the present disclosure, a memory device is provided. The memory device includes a capacitor disposed over a semiconductor substrate, and a conductive plug disposed over the capacitor. The memory device also includes a channel layer disposed over the conductive plug. A top surface of the conductive plug is higher than a bottom surface of the channel layer. The memory device further includes a bit line disposed over the channel layer. A top surface of the channel layer is higher than a bottom surface of the bit line. In addition, the memory device includes a gate dielectric layer and a word line disposed between the conductive plug and the bit line. The gate dielectric layer is disposed between the word line and the channel layer.

In yet another embodiment of the present disclosure, a method for preparing a memory device is provided. The method includes forming a capacitor over a semiconductor substrate, and forming a conductive plug over the capacitor. The method also includes forming a word line over the conductive plug, and forming an opening penetrating through the word line to expose the conductive plug. The method further includes performing a first etching process through the opening to form a first recess in the conductive plug, and forming a channel layer in the opening. In addition, the method includes performing a second etching process to form a second recess in the channel layer, and forming a bit line over the channel layer.

The embodiments of the present disclosure have some advantageous features. By forming recessed conductive plugs and recessed channel layers, contact areas can be increased, which results in a reduction of the contact resistance and an increase of the driving current of the memory device. As a result, the performance of the memory device can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A memory device, comprising:
a capacitor disposed over a semiconductor substrate;
a conductive plug disposed over the capacitor, wherein the conductive plug has a first recessed top surface;
a channel layer disposed over the conductive plug, wherein the channel layer has a second recessed top surface;
a bit line disposed over the channel layer; and
a word line disposed between the conductive plug and the bit line, wherein the channel layer is surrounded by the word line.

2. The memory device of claim 1, wherein the second recessed top surface of the channel layer partially overlaps the first recessed top surface of the conductive plug in a top view.

3. The memory device of claim 1, wherein the channel layer is in direct contact with the first recessed top surface of the conductive plug.

4. The memory device of claim 1, wherein the bit line is in direct contact with the second recessed top surface of the channel layer.

5. The memory device of claim 1, wherein the second recessed top surface of the channel layer is higher than a top surface of the word line.

6. The memory device of claim 1, wherein the bit line has a T-shaped profile.

7. The memory device of claim 1, further comprising:
a gate dielectric layer surrounding the channel layer, wherein the word line is separated from the channel layer by the gate dielectric layer.

8. The memory device of claim 7, wherein the gate dielectric layer is in direct contact with the first recessed top surface of the conductive plug.

9. The memory device of claim 7, wherein a top surface of the gate dielectric layer is higher than the second recessed top surface of the channel layer.

10. The memory device of claim 7, wherein a portion of the channel layer is sandwiched between the bit line and the gate dielectric layer.

11. The memory device of claim 7, wherein the bit line has a lower portion extending into the channel layer and an upper portion disposed over the lower portion, and
wherein the upper portion of the bit line extends laterally beyond opposite edges of the lower portion of the bit line.

12. The memory device of claim 11, wherein a top surface of the gate dielectric layer is covered by and in direct contact with the upper portion of the bit line.

13. The memory device of claim 11, wherein the lower portion of the bit line is separated from the gate dielectric layer.
